(19) United States
(12) Patent Application Publication
(10) Pub. No.: US 2023/0240065 A1
(43) Pub. Date: Jul. 27, 2023

(54) METHOD OF FORMING PLUG FOR SEMICONDUCTOR DEVICE AND SEMICONDUCTOR DEVICE THEREOF

(71) Applicant: HeFeChip Corporation Limited, Hong Kong (HK)

(72) Inventors: Liang Li, Singapore (SG); John Zhang, Altamont, NY (US); Heng Yang, Rexford, NY (US); Huang Liu, Singapore (SG)

(73) Assignee: HeFeChip Corporation Limited, Hong Kong (HK)

(21) Appl. No.: 17/586,379

(22) Filed: Jan. 27, 2022

(51) Int. Cl. H01L 27/108; H01L 21/3105

(52) U.S. Cl. CPC H01L 27/10829; H01L 27/10861; H01L 21/31053

(57) ABSTRACT

A method of forming a plug for a semiconductor device and a semiconductor device thereof are disclosed. The proposed method of forming a plug for a semiconductor device, wherein the semiconductor device includes a deep trench (DT) structure and a storage node configured in the DT structure, comprising: (a) filling a single film in the DT structure and to cover the storage node; and (b) etching back the single film to form the plug located in the DT structure and around the storage node, wherein the single film forms a liner of a single type.

### FIELD OF THE INVENTION

The present invention relates to a method of forming a plug for a semiconductor device and a semiconductor device thereof, in particular to an embedded dynamic random access memory (eDRAM) having a plug for preventing a word line (WL) from shorting to a deep trench (DT) structure therein.

### BACKGROUND OF THE INVENTION

Many different eDRAMs having DT structures were disclosed by the prior arts. With the scaling of semiconductor devices, more eDRAM devices are formed per unit area in a semiconductor chip. Because each eDRAM requires a capacitor to store electrical charges, available device area per capacitor decreases in each generation. In the case of an eDRAM employing a DT capacitor, the minimum capacitance requirement poses a significant challenge. How to improve the efficiency of a DT capacitor of an eDRAM is worthy of further research and improvement. For instance, how to prevent a word line (WL) from shorting to a DT structure of a DT capacitor included in an eDRAM is an important aspect for development in the field. U.S. Pat. No. 6,849,889 disclosed a conductive plug formed for a storage node, but it is not proposed for an isolation purpose. U.S. Pat. No. 8,927,365 disclosed using an ONO stack to prevent a WL from shorting to a fin. However, it didn't disclose preventing a WL from shorting to a DT structure, and it has a complicated film stack. U.S. Pat. No. 7,705,386 disclosed using a shallow trench insulation (STI) concept to prevent a gate from shorting to a DT structure, but it is not suitable for an advanced technology.

Keeping the drawbacks of the prior art in mind, and through the use of robust and persistent experiments and research, the applicant has finally conceived of a method of forming a plug for a semiconductor device and a semiconductor device thereof.

### SUMMARY OF THE INVENTION

It is therefore an objective of the present invention to provide a method of forming a plug for a semiconductor device and a semiconductor device thereof, wherein the plug is used to prevent a WL from shorting to a DT structure both included in the semiconductor device, the proposed method provides a relatively good run to run and within wafer uniformities because a CMP hard stop on liner process is employed, and the final topology profile in a plug area is relatively good because the plug is formed by a single type of liner.

In accordance with the first aspect of the present invention, a method of forming a plug for a semiconductor device, wherein the semiconductor device includes a deep trench (DT) structure and a storage node configured in the DT structure, comprises: (a) filling a single film in the DT structure and to cover the storage node; and (b) etching back the single film to form the plug located in the DT structure and around the storage node, wherein the single film forms a liner of a single type.

In accordance with the second aspect of the present invention, a method for manufacturing a semiconductor device comprises: (a) forming a deep trench (DT) structure; (b) configuring a storage node having an upper end in the DT structure; (c) forming a gap structure between the upper end and the DT structure; and (d) filling a single film of dielectric material in the gap structure and etching back the single film of dielectric material to form a plug including a single type of dielectric material.

In accordance with the third aspect of the present invention, a semiconductor device comprises a deep trench (DT) structure, a storage node configured in the DT structure and having an upper end, a gap structure formed between the upper end and the DT structure, and a plug including a single type of dielectric material and filled in the gap structure.

### BRIEF DESCRIPTION OF THE DRAWINGS

Other objectives, advantages and efficacies of the present invention will be described in detail below taken from the preferred embodiments with reference to the accompanying drawings, in which:

FIG. 1(a) is a cross-sectional view of a semiconductor device including an eDRAM having a DRAM corresponding to a step 1(a)-1 of a manufacturing process according to the first preferred embodiment of the present invention.

FIG. 1(b) is a cross-sectional view of a semiconductor device including an eDRAM having a DRAM corresponding to a step 1(b)-1 of a manufacturing process according to the first preferred embodiment of the present invention.

FIG. 1(c) is a cross-sectional view of a semiconductor device including an eDRAM having an SRAM corresponding to a step 1(c)-1 of a manufacturing process according to the first preferred embodiment of the present invention.

FIG. 2(a) is a cross-sectional view of a semiconductor device including an eDRAM having a DRAM corresponding to a step 2(a)-1 of a manufacturing process according to the first preferred embodiment of the present invention.

FIG. 2(b) is a cross-sectional view of a semiconductor device including an eDRAM having an SRAM corresponding to a step 2(b)-1 of a manufacturing process according to the first preferred embodiment of the present invention.

FIG. 3(a) is a cross-sectional view of a semiconductor device including an eDRAM having a DRAM corresponding to a step 3(a)-1 of a manufacturing process according to the first preferred embodiment of the present invention.

FIG. 3(b) is a cross-sectional view of a semiconductor device including an eDRAM having an SRAM corresponding to a step 3(b)-1 of a manufacturing process according to the first preferred embodiment of the present invention.

FIG. 4(a) is a cross-sectional view of a semiconductor device including an eDRAM having a DRAM corresponding to a step 4(a)-1 of a manufacturing process according to the first preferred embodiment of the present invention.

FIG. 4(b) is a cross-sectional view of a semiconductor device including an eDRAM having an SRAM corresponding to a step 4(b)-1 of a manufacturing process according to the first preferred embodiment of the present invention.

FIG. 5(a) is a cross-sectional view of a semiconductor device including an eDRAM having a DRAM corresponding to a step 5(a)-1 of a manufacturing process according to the first preferred embodiment of the present invention.

FIG. 5(b) is a cross-sectional view of a semiconductor device including an eDRAM having an SRAM corresponding to a step 5(b)-1 of a manufacturing process according to the first preferred embodiment of the present invention.

FIG. 6(a) is a cross-sectional view of a semiconductor device including an eDRAM having a DRAM corresponding to a step 6(a)-1 of a manufacturing process according to the first preferred embodiment of the present invention.

FIG. 6(b) is a cross-sectional view of a semiconductor device including an eDRAM having an SRAM corresponding to a step 6(b)-1 of a manufacturing process according to the first preferred embodiment of the present invention.

FIG. 7(a) is a cross-sectional view of a semiconductor device including an eDRAM having a DRAM corresponding to a step 7(a)-1 of a manufacturing process according to the first preferred embodiment of the present invention.

FIG. 7(b) is a cross-sectional view of a semiconductor device including an eDRAM having an SRAM corresponding to a step 7(b)-1 of a manufacturing process according to the first preferred embodiment of the present invention.

FIG. 7(c) is a cross-sectional view of a semiconductor device including an eDRAM having a DRAM corresponding to a step 7(c)-1 of a manufacturing process according to the first preferred embodiment of the present invention.

FIG. 7(d) is a cross-sectional view of a semiconductor device including an eDRAM having an SRAM corresponding to a step 7(d)-1 of a manufacturing process according to the first preferred embodiment of the present invention.

FIG. 7(e) is a cross-sectional view of a semiconductor device including an eDRAM having a DRAM corresponding to a step 7(e)-1 of a manufacturing process according to the first preferred embodiment of the present invention.

FIG. 7(f) is a cross-sectional view of a semiconductor device including an eDRAM having an SRAM corresponding to a step 7(f)-1 of a manufacturing process according to the first preferred embodiment of the present invention.

FIG. 8(a) is a cross-sectional view of a semiconductor device including an eDRAM having a DRAM corresponding to a step 8(a)-1 of a manufacturing process according to the first preferred embodiment of the present invention.

FIG. 8(b) is a cross-sectional view of a semiconductor device including an eDRAM having an SRAM corresponding to a step 8(b)-1 of a manufacturing process according to the first preferred embodiment of the present invention.

FIG. 9(a) is a cross-sectional view of a semiconductor device including an eDRAM having a DRAM corresponding to a step 9(a)-1 of a manufacturing process according to the first preferred embodiment of the present invention.

FIG. 9(b) is a cross-sectional view of a semiconductor device including an eDRAM having an SRAM corresponding to a step 9(b)-1 of a manufacturing process according to the first preferred embodiment of the present invention.

FIG. 9(c) is a cross-sectional view of a semiconductor device including an eDRAM having a DRAM corresponding to a step 9(c)-1 of a manufacturing process according to the first preferred embodiment of the present invention.

FIG. 9(d) is a cross-sectional view of a semiconductor device including an eDRAM having an SRAM corresponding to a step 9(d)-1 of a manufacturing process according to the first preferred embodiment of the present invention.

FIG. 9(e) is a cross-sectional view of a semiconductor device including an eDRAM having a DRAM corresponding to a step 9(e)-1 of a manufacturing process according to the first preferred embodiment of the present invention.

FIG. 9(f) is a cross-sectional view of a semiconductor device including an eDRAM having an SRAM corresponding to a step 9(f)-1 of a manufacturing process according to the first preferred embodiment of the present invention.

FIG. 9(g) is a cross-sectional view of a semiconductor device including an eDRAM having a DRAM corresponding to a step 9(g)-1 of a manufacturing process according to the first preferred embodiment of the present invention.

FIG. 9(h) is a cross-sectional view of a semiconductor device including an eDRAM having an SRAM corresponding to a step 9(h)-1 of a manufacturing process according to the first preferred embodiment of the present invention.

FIG. 10(a) is a cross-sectional view of a semiconductor device including an eDRAM having a DRAM corresponding to a step 10(a)-1 of a manufacturing process according to the first preferred embodiment of the present invention.

FIG. 10(b) is a cross-sectional view of a semiconductor device including an eDRAM having an SRAM corresponding to a step 10(b)-1 of a manufacturing process according to the first preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purposes of illustration and description only; it is not intended to be exhaustive or to be limited to the precise form disclosed.

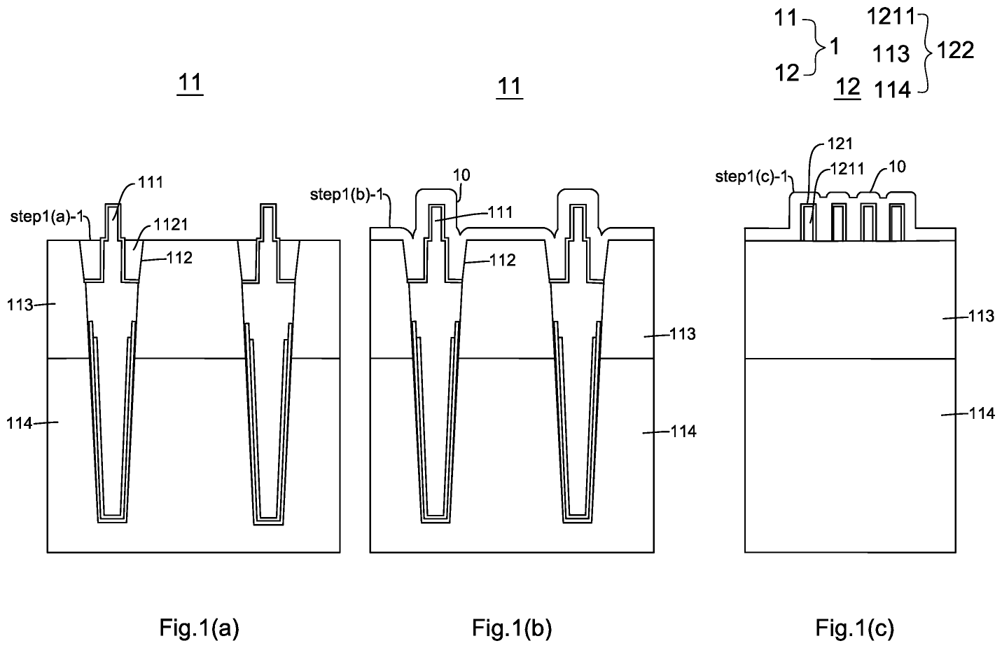

FIG. 1(a) shows a cross-sectional view of a semiconductor device including an eDRAM having a DRAM corresponding to a step 1(a)-1 of a manufacturing process according to the first preferred embodiment of the present invention. In the step 1(a)-1, it includes: (i) providing a DRAM 11 included in an eDRAM 1 (see FIG. 1(c)) of a semiconductor device and having a substrate 114, a buried oxide (BOX) 113 configured on the substrate 114, a deep trench (DT) structure 112 having a gap structure 1121, and etched through the BOX 113 and into the substrate 114, and a storage node 111 configured in the DT structure 112.

FIG. 1(b) shows a cross-sectional view of a semiconductor device including an eDRAM having a DRAM corresponding to a step 1(b)-1 of a manufacturing process according to the first preferred embodiment of the present invention. In the step 1(b)-1, it includes: (i) forming a single film of dielectric material to fill in the DT structure 112 and to cover the storage node 111, wherein the single film of dielectric material is a SiN liner 10.

FIG. 1(c) shows a cross-sectional view of a semiconductor device including an eDRAM having an SRAM corresponding to a step 1(c)-1 of a manufacturing process according to the first preferred embodiment of the present invention. In the step 1(c)-1, it includes: (i) providing an SRAM 12 included in the eDRAM 1 and having the substrate 114, the buried oxide (BOX) 113 configured on the substrate 114, an SOI 1211 configured on the BOX 113, and a fin 121 configured on top of the SOI 1211; (ii) providing an SOI wafer 122 including the substrate 114, the BOX 113 and the SOI 1211, wherein the eDRAM 1 includes the DRAM 11 and the SRAM 12; and (iii) forming a single layer of the SiN liner 10 on top of the BOX 113 and the fin 121, wherein the SOI 1211 included in the DRAM 11 (on top of the BOX 113 in FIG. 1(a), not shown) and the SOI 1211 included in the SRAM 12 have the same crystal orientation.

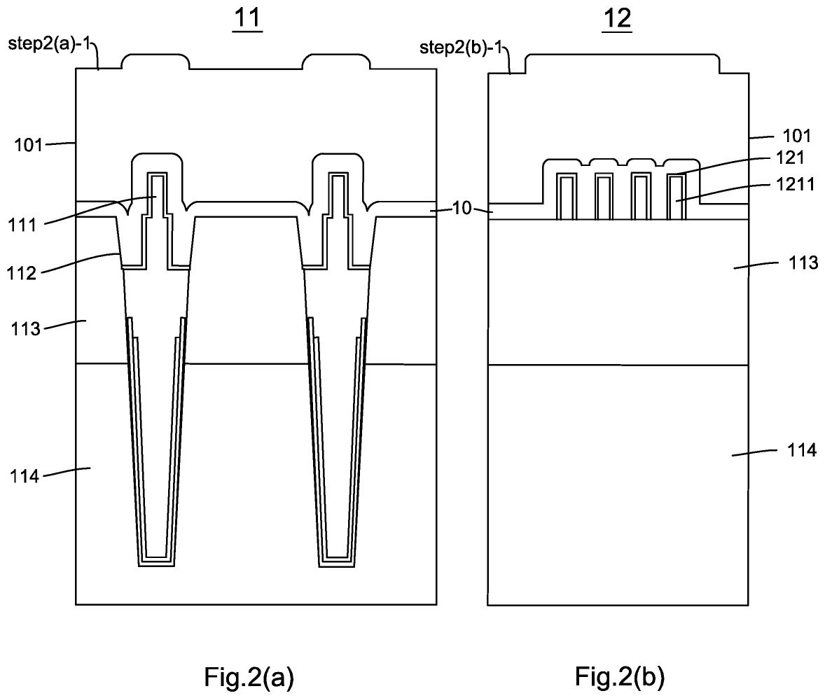

FIG. 2(a) shows a cross-sectional view of a semiconductor device including an eDRAM having a DRAM corresponding to a step 2(a)-1 of a manufacturing process according to the first preferred embodiment of the present invention. In the step 2(a)-1, it includes: (i) depositing a high aspect ratio process (HARP) film or a HARP layer 101 on top of the SiN liner 10 included in the DRAM 11.

FIG. 2(b) shows a cross-sectional view of a semiconductor device including an eDRAM having an SRAM corresponding to a step 2(b)-1 of a manufacturing process according to the first preferred embodiment of the present invention. In the step 2(b)-1, it includes: (i) depositing a high aspect ratio process (HARP) film or a HARP layer 101 on top of the SiN liner 10 included in the SRAM 12.

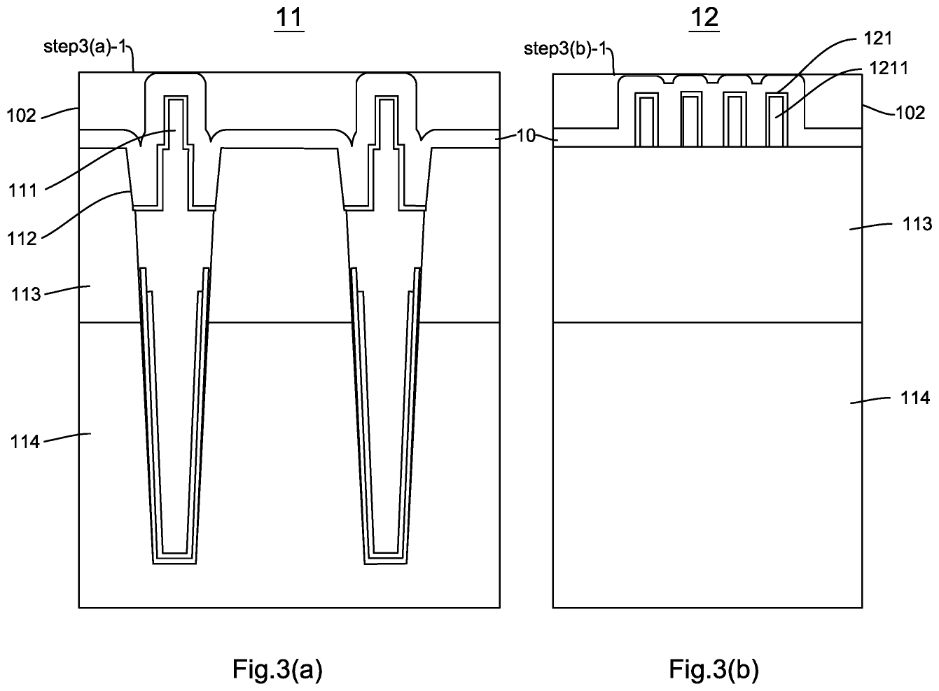

FIG. 3(a) shows a cross-sectional view of a semiconductor device including an eDRAM having a DRAM corresponding to a step 3(a)-1 of a manufacturing process according to the first preferred embodiment of the present invention. In the step 3(a)-1, it includes: (i) polishing the HARP film or the HARP layer 101 in the DRAM 11 with a Chemical Mechanical Polishing (CMP); and (ii) allowing the CMP to be stopped on the SiN liner 10 in the DRAM 11 to form a HARP CMP 102.

FIG. 3(b) shows a cross-sectional view of a semiconductor device including an eDRAM having an SRAM corresponding to a step 3(b)-1 of a manufacturing process according to the first preferred embodiment of the present invention. In the step 3(b)-1, it includes: (i) polishing the HARP film or the HARP layer 101 in the SRAM 12 with a Chemical Mechanical Polishing (CMP); and (ii) allowing the CMP to be stopped on the SiN liner 10 in the SRAM 12 to form a HARP CMP 102.

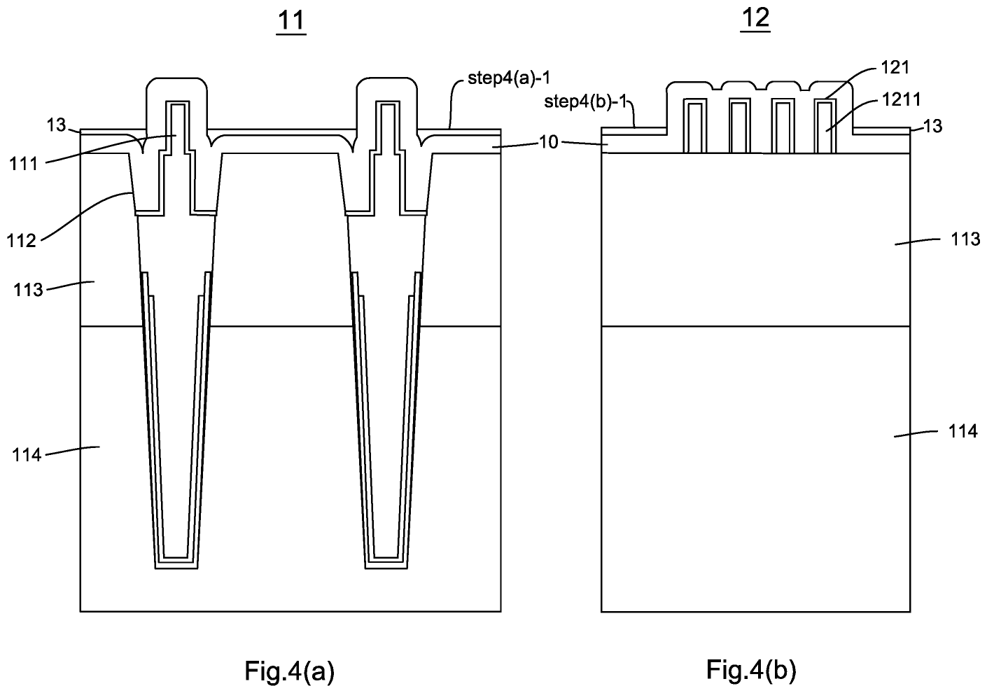

FIG. 4(a) shows a cross-sectional view of a semiconductor device including an eDRAM having a DRAM corresponding to a step 4(a)-1 of a manufacturing process according to the first preferred embodiment of the present invention. FIG. 4(b) shows a cross-sectional view of a semiconductor device including an eDRAM having an SRAM corresponding to a step 4(b)-1 of a manufacturing process according to the first preferred embodiment of the present invention. In the steps 4(a)-1 for the DRAM and 4(b)-1 for the SRAM, they respectively include: (i) using a wet etch or a dry etch to let the HARP film or the HARP layer 101 in the DRAM 11/the SRAM 12 be partially recessed to form a partially HARP recess 13, wherein the dry etch is a Reactive-Ion Etch (RIE).

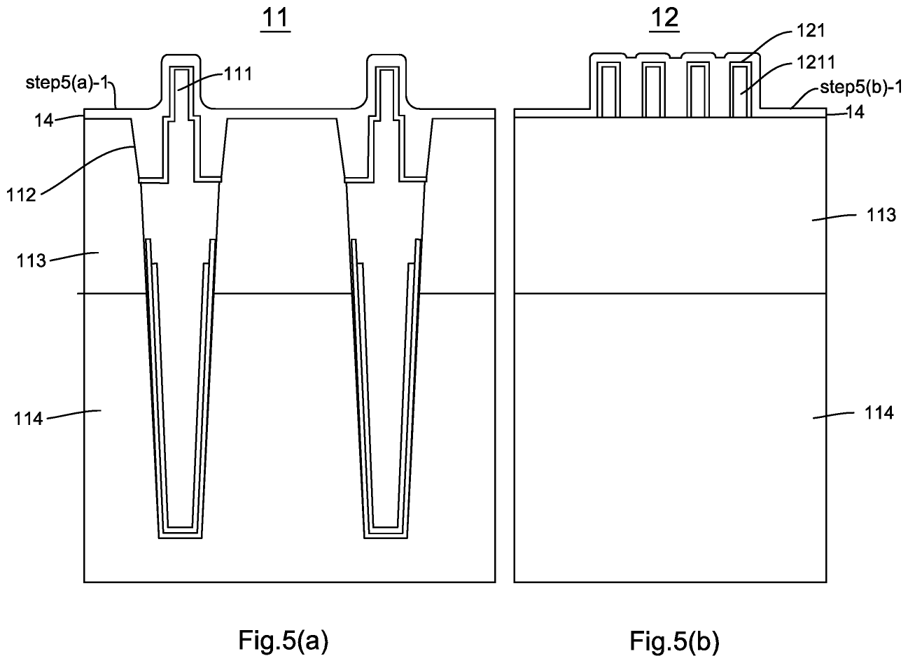

FIG. 5(a) shows a cross-sectional view of a semiconductor device including an eDRAM having a DRAM corresponding to a step 5(a)-1 of a manufacturing process according to the first preferred embodiment of the present invention. FIG. 5(b) shows a cross-sectional view of a semiconductor device including an eDRAM having an SRAM corresponding to a step 5(b)-1 of a manufacturing process according to the first preferred embodiment of the present invention. In the steps 5(a)-1 for the DRAM and 5(b)-1 for the SRAM, they respectively include: (i) using a non-selective wet etch both in the DRAM 11 and the SRAM 12 to allow the partial HARP recess 13 to be removed, and the SiN liner 10 to be recessed in a range of 10-15 nm to form a recessed SiN liner 14.

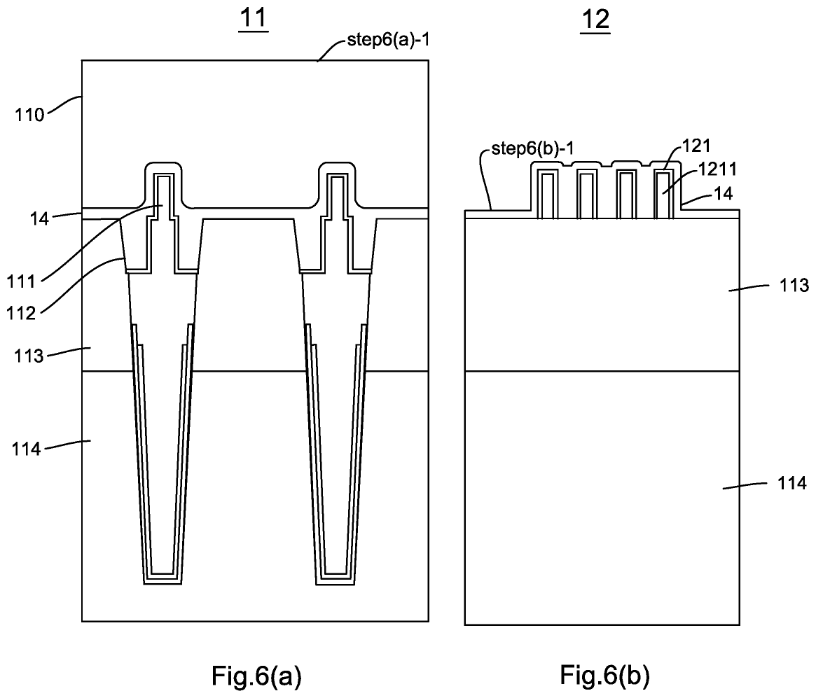

FIG. 6(a) shows a cross-sectional view of a semiconductor device including an eDRAM having a DRAM corresponding to a step 6(a)-1 of a manufacturing process according to the first preferred embodiment of the present invention. In the step 6(a)-1, it includes: (i) forming a Plug mask 110 on top of the recessed silicon nitride liner 14 in the DRAM 11 so as to remove the recessed SiN liner 14 from the SRAM 12 next.

FIG. 6(b) shows a cross-sectional view of a semiconductor device including an eDRAM having an SRAM corresponding to a step 6(b)-1 of a manufacturing process according to the first preferred embodiment of the present invention. In the step 6(b)-1, it includes: (i) the recessed SiN liner 14 in the SRAM 12 region is not covered by the Plug mask 110.

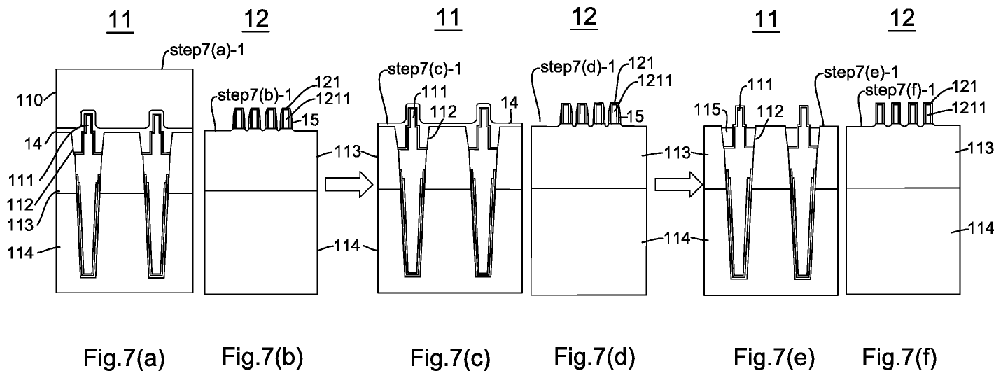

FIGS. 7(a)-7(f) show a first embodiment of a manufacturing process regarding the removal of the recessed SiN liner from the DRAM and the SRAM according to the first preferred embodiment of the present invention.

FIG. 7(a) shows a cross-sectional view of a semiconductor device including an eDRAM having a DRAM corresponding to a step 7(a)-1 of a manufacturing process according to the first preferred embodiment of the present invention. In the step 7(a)-1, it includes: (i) protecting the recessed SiN liner 14 in the DRAM 11 from being etched via the Plug mask 110 when a dry etch is used to remove most of the recessed SiN liner 14 deposited on top of the fin 121 of the SRAM 12.

FIG. 7(b) shows a cross-sectional view of a semiconductor device including an eDRAM having an SRAM corresponding to a step 7(b)-1 of a manufacturing process according to the first preferred embodiment of the present invention. In the step 7(b)-1, it includes: (i) using the dry etch to remove most of the recessed SiN liner 14 deposited on top of the fin 121 of the SRAM 12 to have a remaining SiN liner 15 thereon.

FIG. 7(c) shows a cross-sectional view of a semiconductor device including an eDRAM having a DRAM corresponding to a step 7(c)-1 of a manufacturing process according to the first preferred embodiment of the present invention. In the step 7(c)-1, it includes: (i) removing the Plug mask 110 included in the DRAM 11 via a resist strip process.

FIG. 7(d) shows a cross-sectional view of a semiconductor device including an eDRAM having an SRAM corresponding to a step 7(d)-1 of a manufacturing process according to the first preferred embodiment of the present invention. In the step 7(d)-1, it includes: (i) the remaining SiN liner 15 and fin 121 in the SRAM 12 would not be etched as the Plug mask 110 is removed.

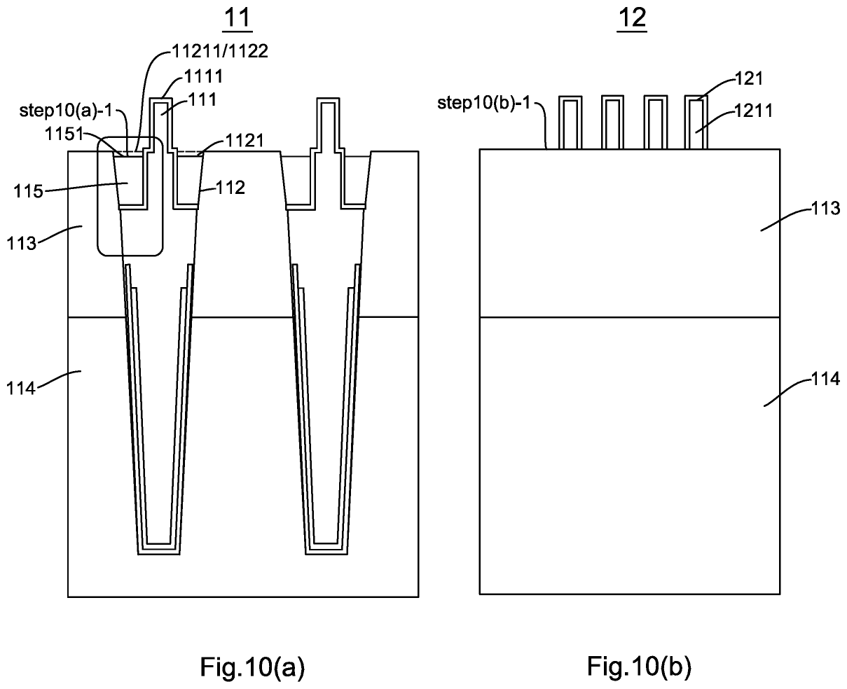

FIG. 7(e) shows a cross-sectional view of a semiconductor device including an eDRAM having a DRAM corresponding to a step 7(e)-1 of a manufacturing process according to the first preferred embodiment of the present invention. In the step 7(e)-1, it includes: (i) using a wet etch to remove the recessed SiN liner 14 on top of the BOX 113 and the storage node 111 both included in the DRAM 11 and to reach a desired depth in the DT structure to form the plug 115 (see FIG. 10(a)).

FIG. 7(f) shows a cross-sectional view of a semiconductor device including an eDRAM having an SRAM corresponding to a step 7(f)-1 of a manufacturing process according to the first preferred embodiment of the present invention. In the step 7(f)-1, it includes: (i) using a wet etch to remove the remaining SiN liner 15 on the surface of the fin 121 in the SRAM 12.

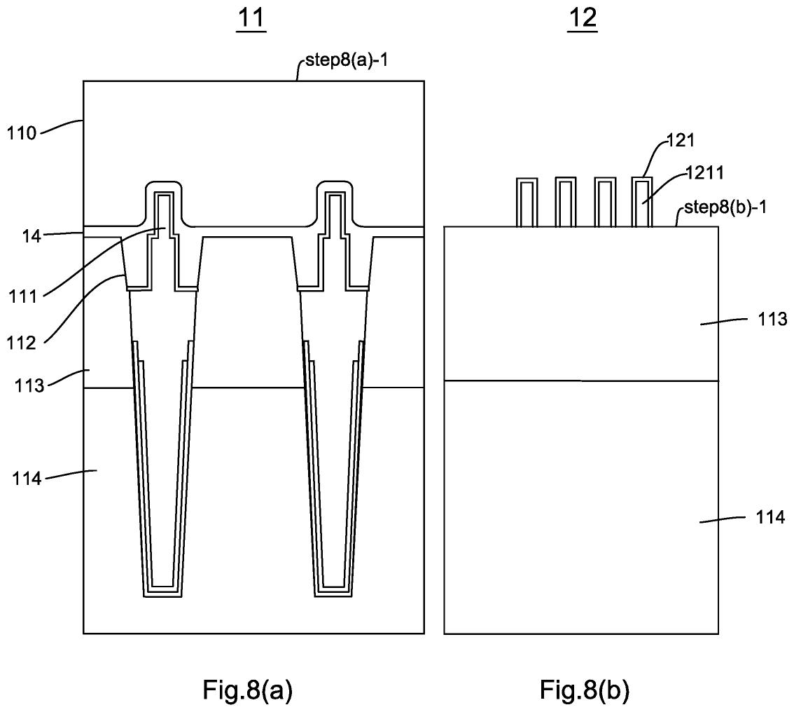

FIGS. 8(a)-8(b) show a second embodiment of a manufacturing process regarding the removal of the recessed SiN liner from the SRAM according to the first preferred embodiment of the present invention.

FIG. 8(a) shows a cross-sectional view of a semiconductor device including an eDRAM having a DRAM corresponding to a step 8(a)-1 of a manufacturing process according to the first preferred embodiment of the present invention. FIG. 8(b) shows a cross-sectional view of a semiconductor device including an eDRAM having an SRAM corresponding to a step 8(b)-1 of a manufacturing process according to the first preferred embodiment of the present invention. In the steps 8(a)-1 for the DRAM and 8(b)-1 for the SRAM, they respectively include: (i) after the step 6(a)-1, the recessed SiN liner 14 in the DRAM 11 would not be etched as the recessed SiN liner 14 in the SRAM 12 is removed; and (ii) after the step 6(b)-1, a wet etch is used to remove the recessed SiN liner 14 in the SRAM 12, wherein the wet etch uses a mixture of fluorosilicic acid and silicic acid. The typical process temperature of the wet etch is less than 100° C. and the typical etch selectivity for nitride versus oxide etch is about 200:1 to about 2000:1.

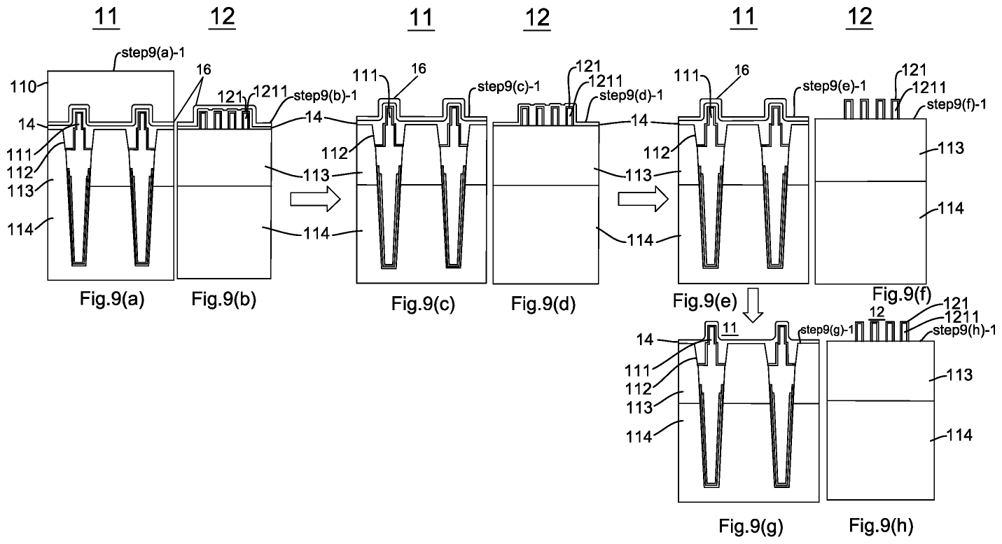

FIGS. 9(a)-9(h) show a third embodiment of a manufacturing process regarding the removal of the recessed SiN liner from the SRAM according to the first preferred embodiment of the present invention.

FIG. 9(a) shows a cross-sectional view of a semiconductor device including an eDRAM having a DRAM corresponding to a step 9(a)-1 of a manufacturing process according to the first preferred embodiment of the present invention. FIG. 9(b) shows a cross-sectional view of a semiconductor device including an eDRAM having an SRAM corresponding to a step 9(b)-1 of a manufacturing process according to the first preferred embodiment of the present invention. In the steps 9(a)-1 for the DRAM and 9(b)-1 for the SRAM, they respectively include: (i) forming an a-Si hardmask 16 on top of the recessed SiN liner 14 in the DRAM 11 (see FIG. 5(a)) and forming a Plug mask 110 on top of the a-Si hardmask 16 therein (see FIG. 9(a)); and (ii) forming an a-Si hardmask 16 on top of the recessed SiN liner 14 in the SRAM 12 (see FIG. 5(b)).

FIG. 9(c) shows a cross-sectional view of a semiconductor device including an eDRAM having a DRAM corresponding to a step 9(c)-1 of a manufacturing process according to the first preferred embodiment of the present invention. In the step 9(c)-1, it includes: (i) using a resist strip process to remove the Plug mask 110 on top of the a-Si hardmask 16 in the DRAM 11.

FIG. 9(d) shows a cross-sectional view of a semiconductor device including an eDRAM having an SRAM corresponding to a step 9(d)-1 of a manufacturing process according to the first preferred embodiment of the present invention. In the step 9(d)-1, it includes: (i) using a wet etch to selectively remove the a-Si hardmask 16 on top of the recessed SiN liner 14 in the SRAM 12 as the Plug mask 110 on top of the a-Si hardmask 16 in the DRAM 11 is removed, wherein a hot NH4OH is used to remove the a-Si hardmask 16.

FIG. 9(e) shows a cross-sectional view of a semiconductor device including an eDRAM having a DRAM corresponding to a step 9(e)-1 of a manufacturing process according to the first preferred embodiment of the present invention. FIG. 9(f) shows a cross-sectional view of a semiconductor device including an eDRAM having an SRAM corresponding to a step 9(f)-1 of a manufacturing process according to the first preferred embodiment of the present invention. In the steps 9(e)-1 for the DRAM and 9(f)-1 for the SRAM, they respectively include: (i) allowing the a-Si hardmask 16 on top of the recessed SiN liner 14 in the DRAM 11 (as shown in FIG. 9(c)) to be the same; and (ii) removing the recessed SiN liner 14 on top of the fin 121 of the SRAM 12 (as shown in FIG. 5(b)) by a wet etch, wherein a hot H3PO4 is used to remove the recessed SiN liner 14.

FIG. 9(g) shows a cross-sectional view of a semiconductor device including an eDRAM having a DRAM corresponding to a step 9(g)-1 of a manufacturing process according to the first preferred embodiment of the present invention. In the step 9(g)-1, it includes: (i) using a wet etch to remove the a-Si hardmask 16 on top of the recessed SiN liner 14 in the DRAM 11, wherein a hot NH4OH is used to remove the a-Si hardmask 16 in the DRAM 11.

FIG. 9(h) shows a cross-sectional view of a semiconductor device including an eDRAM having an SRAM corresponding to a step 9(h)-1 of a manufacturing process according to the first preferred embodiment of the present invention. In the step 9(h)-1, it includes: (i) the fin 121 in the SRAM 12 would not be etched as the a-Si hardmask 16 is removed.

FIG. 10(a) shows a cross-sectional view of a semiconductor device including an eDRAM having a DRAM corresponding to a step 10(a)-1 of a manufacturing process according to the first preferred embodiment of the present invention. In the step 10(a)-1, it includes: (i) the step 7(e)-1 (as shown in FIG. 7(e)); or (i) the step 8(a)-1; (ii) the step 7(c)-1; and (iii) the step 7(e)-1; or (i) the step 9(g)-1 (as shown in FIG. 9(g)); and (ii) the step 7(e)-1.

According to the second preferred embodiment of the present invention, a method of forming a plug 115 for a semiconductor device 1, wherein the semiconductor device 1 includes a deep trench (DT) structure 112 and a storage node 111 configured in the DT structure 112, includes: (a) filling a single film in the DT structure 112 and to cover the storage node 111 (see the above-mentioned step 1(b)-1); and (b) etching back the single film to form the plug 115 located in the DT structure 112 and around the storage node 111, wherein the single film forms a liner of a single type, and the liner of the single type is a silicon nitride liner (e.g., see the combination of the above-mentioned steps 2(a)-1, 3(a)-1, 4(a)-1, 5(a)-1, 6(a)-1, 7(c)-1 and 7(e)-1). The step (a) further comprises a step (a1): filling the DT structure 112 with the silicon nitride liner (see the above-mentioned step 1(b)-1); and a step (a2): forming a high aspect ratio process (HARP) layer 101 on the silicon nitride liner 10 (see the above-mentioned step 2(a)-1). The step (b) further comprises a step (b1): polishing the HARP layer 101 with a Chemical Mechanical Polishing (CMP) and allowing the CMP to be stopped on the silicon nitride liner 10 (see the above-mentioned step 3(a)-1); (b2): using a wet etch or a dry etch to partially recess the HARP layer 101 (see the above-mentioned step 4(a)-1); (b3): using a non-selective wet etch to recess the HARP layer 101 and the silicon nitride liner 10 (see the above-mentioned steps 5(a)-1 and 5(b)-1); and (b4): recessing the silicon nitride liner 10 by an etching process to a desired depth in the DT structure 112 to complete the plug 115 (see the above-mentioned step 7(e)-1 or 10(a)-1).

According to the third preferred embodiment of the present disclosure, a method for manufacturing a semiconductor device 1 comprises: (a) forming a deep trench (DT) structure 112; (b) configuring a storage node 111 having an upper end 1111 in the DT structure 112; (c) forming a gap structure 1121 between the upper end 1111 and the DT structure 112 (see the above-mentioned step 1(a)-1); and (d) filling a single film of dielectric material in the gap structure 1121 and etching back the single film of dielectric material to form a plug 115 including a single type of dielectric material (e.g., see the combination of the above-mentioned steps 2(a)-1, 3(a)-1, 4(a)-1, 5(a)-1, 6(a)-1, 7(c)-1 and 7(e)-1). The step (d) further comprises a step (d1): etching the single film of dielectric material back to a desired depth in the gap structure 1121 to form a liner of a single type, wherein the semiconductor device 1 is an embedded dynamic random access memory (eDRAM) 1, and the single type liner includes the single type of dielectric material, surrounds the storage node 111 and forms the plug 115 (see the above-mentioned step 7(e)-1, or step 10(a)-1), and the plug 115 is used to prevent a WL (not shown) from shorting to the DT structure 112.

According to the fourth preferred embodiment of the present invention, a semiconductor device 1 comprises a deep trench (DT) structure 112; a storage node 111 configured in the DT structure 112 and having an upper end 1111; a gap structure 1121 formed between the upper end 1111 and the DT structure 112; and a plug 115 including a single type of dielectric material and filled in the gap structure 1121 (see the above-mentioned step 10(a)-1). The semiconductor device 1 is an embedded dynamic random access memory (eDRAM) 1 including a dynamic random access memory (DRAM) 11 and a static random access memory (SRAM) 12 (see the above-mentioned step 1(c)-1), and the plug 115 is a liner and the liner is used to prevent a WL (not shown) from shorting to the DT structure 112. The DT structure 112 has a first upper surface 1122, the gap structure 1121 has a second upper surface 11211, and the first upper surface 1122 and the second upper surface 11211 are flush. The plug 115 has a third upper surface 1151, and the third upper surface 1151 is lower than the first upper surface 1122 (see the above-mentioned step 10(a)-1).

FIG. 10(b) shows a cross-sectional view of a semiconductor device including an eDRAM having an SRAM corresponding to a step 10(b)-1 of a manufacturing process according to the first preferred embodiment of the present invention. In the step 10(b)-1, it includes: (i) the step 7(f)-1; or (i) the step 8(b)-1; or the step 9(h).

According to the above-mentioned descriptions, the present invention discloses a method of forming a plug for a semiconductor device and a semiconductor device thereof, wherein the plug is used to prevent a WL from shorting to a DT structure both included in the semiconductor device, the proposed method provides a relatively good run to run and within wafer uniformities because a CMP hard stop on liner process is employed, and the final topology profile in a plug area is relatively good because the plug is formed by a single type of liner, which demonstrates the non-obviousness and novelty.

While the invention has been described in terms of what is presently considered to be the most practical and preferred embodiments, it is to be understood that the invention need not be limited to the disclosed embodiments. Therefore, it is intended to cover various modifications and similar configurations included within the spirit and scope of the appended claims, which are to be accorded with the broadest interpretation so as to encompass all such modifications and similar structures.

What is claimed is:

1. A method of forming a plug for a semiconductor device, wherein the semiconductor device includes a deep trench (DT) structure and a storage node configured in the DT structure, comprising:
(a) filling a single film in the DT structure and to cover the storage node; and
(b) etching back the single film to form the plug located in the DT structure and around the storage node, wherein the single film forms a liner of a single type.

2. The method according to claim 1, wherein the semiconductor device is an embedded dynamic random access memory (eDRAM), the eDRAM includes a Silicon on Insulator (SOI) and a buried oxide (BOX) under the SOI, and the plug is formed in a range of the BOX under the SOI.

3. The method according to claim 1, wherein the semiconductor device further includes a substrate, and the step (a) further comprises a step (a0): providing an SOI wafer, wherein the SOI wafer includes the substrate, the BOX and the SOI.

4. The method according to claim 2, wherein the eDRAM further includes a dynamic random access memory (DRAM) and a static random access memory (SRAM), and the SOI included in the DRAM and the SOI included in the SRAM have the same crystal orientation.

5. The method according to claim 2, wherein the eDRAM further includes a word line (WL), and the plug is used to prevent the WL from shorting to the DT structure.

6. The method according to claim 1, wherein the liner of the single type is a silicon nitride liner.

7. The method according to claim 6, wherein the step (a) comprises a step (a1): filling the DT structure with the silicon nitride liner.

8. The method according to claim 7, wherein the step (a) further comprises a step (a2): forming a high aspect ratio process (HARP) layer on the silicon nitride liner.

9. The method according to claim 8, wherein the step (b) further comprises a step (b1): polishing the HARP layer with a Chemical Mechanical Polishing CMP) and allowing the CMP to be stopped on the silicon nitride liner.

10. The method according to claim 9, wherein the step (b) further comprises a step (b2): using a wet etch or a dry etch to partially recess the HARP layer.

11. The method according to claim 10, wherein the step (b) further comprises a step (b3): using a non-selective wet etch to recess the HARP layer and the silicon nitride liner.

12. The method according to claim 11, wherein the step (b) further comprises a step (b4): recessing the silicon nitride liner by an etching process to a desired depth in the DT structure to complete the plug.

13. The method according to claim 12, wherein the etching process is a wet etch, and the silicon nitride liner has an etch selectivity for silicon nitride versus silicon oxide being larger than 100:1.

14. A method for manufacturing a semiconductor device, comprising:
(a) forming a deep trench (DT) structure;
(b) configuring a storage node having an upper end in the DT structure;
(c) forming a gap structure between the upper end and the DT structure; and
(d) filling a single film of dielectric material in the gap structure and etching back the single film of dielectric material to form a plug including a single type of dielectric material.

15. The method according to claim 14, wherein the semiconductor device is an embedded dynamic random access memory (eDRAM), and the step (d) further comprises a step (d1): etching the single film of dielectric material back to a desired depth in the gap structure to form a liner of a single type, wherein the single type liner includes the single type of dielectric material, surrounds the storage node and forms the plug, and the plug is used to prevent a WL from shorting to the DT structure.

16. A semiconductor device, comprising:
a deep trench (DT) structure;
a storage node configured in the DT structure and having an upper end;
a gap structure formed between the upper end and the DT structure; and
a plug including a single type of dielectric material and filled in the gap structure.

17. The semiconductor device according to claim 16, further comprising a world line (WL), wherein the semiconductor device is an embedded dynamic random access memory (eDRAM) including a dynamic random access memory (DRAM) and a static random access memory (SRAM), the plug is a liner and the liner is used to prevent the WL from shorting to the DT structure.

18. The semiconductor device according to claim 17, wherein the liner is a silicon nitride liner, and the silicon nitride liner has an etch selectivity for silicon nitride versus silicon oxide being larger than 100:1.

19. The semiconductor device according to claim 16, wherein the DT structure has a first upper surface, the gap structure has a second upper surface, and the first and the second upper surfaces are flush.

20. The semiconductor device according to claim 19, wherein the plug has a third upper surface, and the third upper surface is lower than the first upper surface.
